(19) United States
(12) Patent Application Publication
(10) Pub. No.: US 2021/0210353 A1
(43) Pub. Date: Jul. 8, 2021

(54) METHOD OF PROCESSING SUBSTRATE HAVING POLYSILICON LAYER AND SYSTEM THEREOF

(71) Applicant: XIA TAI XIN SEMICONDUCTOR (QING DAO) LTD., Qingdao (CN)

(72) Inventor: SUN-WUNG LEE, Singapore (SG)

(21) Appl. No.: 16/736,579

(22) Filed: Jan. 7, 2020

(51) Int. Cl. H01L 21/306; B08B 3/08; B24B 7/22; B24B 53/017

(52) U.S. Cl. CPC H01L 21/30625; B24B 53/017; B24B 7/228; B08B 3/08

(57) ABSTRACT

The present disclosure provides a method of processing a substrate having a polysilicon layer. The substrate is loaded to a processing system. The processing system includes a polishing module and a cleaning module coupled to the polishing module. The polishing module includes at least a first platen and a second platen. Each of the platens includes a polishing pad for polishing the substrate. An abrasive slurry is applied on the first platen of the polishing module to perform planarization of the polysilicon layer. After planarization, the surface polysilicon layer is treated by a non-ionic surfactant solution to change the surface property to hydrophilic. In the post-CMP cleaning process, organic contaminates on the surface of the polysilicon layer are easily removed by HF solution and SC1 solution, without the need of additional H₂SO₄ cleaning process.

### FIELD

The present disclosure generally relates to a method of processing a semiconductor substrate having polysilicon layer. More specifically, the present disclosure relates to a method of post-CMP treatment of a polysilicon layer of a semiconductor substrate by non-ionic surfactants.

### BACKGROUND

Chemical-mechanical polishing or chemical-mechanical planarization (CMP) is accomplished by holding the semiconductor wafer against a rotating polishing surface, or otherwise moving the wafer relative to the polishing surface, under controlled conditions of temperature, pressure, and chemical composition. The polishing surface, which may be a planar pad formed of a relatively soft and porous material such as a blown polyurethane, wetted with a chemically reactive and abrasive aqueous slurry. The aqueous slurry, which may be either acidic or basic, typically includes abrasive particles, reactive chemical agents such as transition metal chelated salts or oxidizers, and adjuvants such as solvents, buffers, and passivating agents. In the slurry, the salts or other agents provide the chemical etching action, whereas the abrasive particles, in cooperation with the polishing pad, provide the mechanical polishing action.

Polysilicon layers are commonly used as hard mask for forming patterns on a desired layer. The polysilicon layer has a hydrophobic surface. Organic contaminates (e.g., polish pad side product, clean brush debris, and surfactant of slurry) from subsequent planarization processes are likely to adhere to the surface of the polysilicon layer. Besides cleaning processes by using hydrogen fluoride (HF) solution and Standard Cleaning 1 (SC1) after the CMP process, an additional cleaning process by H₂SO₄ solution is usually required to remove the contaminates from the surface of the polysilicon layer to prevent defects.

Accordingly, there remains a need to provide a method of polishing and cleaning the polysilicon layer to overcome the aforementioned problems.

### SUMMARY

In view of above, the present disclosure is directed to a method of processing a substrate having a polysilicon layer and system thereof. The present disclosure uses a non-ionic surfactant solution to change the surface property of the polysilicon layer from hydrophobic to hydrophilic. Therefore, in the post-CMP cleaning process, organic contaminates on the surface of the polysilicon layer can be easily removed by HF solution and SC1 solution without an additional H₂SO₄ cleaning process.

An implementation of the present disclosure is directed to a method of processing a substrate having a polysilicon layer. As shown in FIG. 4, the method includes actions S401 to S407. In action S401, the substrate is loaded on a processing system. The processing system includes a polishing module and a cleaning module coupled to the polishing module. The polishing module includes at least a first platen and a second platen. Each of the first platen and the second platen includes a polishing pad for polishing the substrate. In action S402, an abrasive slurry is applied on the first platen of the polishing module. In action S403, the polysilicon layer of the substrate is planarized on the polishing pad of the first platen by the abrasive slurry. In action S404, a surfactant solution is applied on the polishing pad of the second platen. In action S405, the polysilicon layer of the substrate is treated on the polishing pad of the second platen by the surfactant solution. In action S406, the substrate is moved from the polishing module to the cleaning module. In action S407, the polysilicon layer of the substrate is cleaned in the cleaning module.

Another implementation of the present disclosure is directed to a processing system for processing a substrate having a polysilicon layer. The processing system includes a polishing module, a cleaning module, and a transfer region disposed between the polishing module and the cleaning module. The polishing module includes at least a first platen and a second platen. The first platen includes a first nozzle configured to provide an abrasive slurry for planarizing the polysilicon layer of the substrate. The second platen includes a second nozzle configured to provide a surfactant solution for treating the polysilicon layer. The cleaning module is coupled to the polishing module for cleaning the substrate. The transfer region includes a robot configured to transfer the substrate between the polishing module and the cleaning module.

As described above, the method and processing system of the implementations of the present disclosure use a non-ionic surfactant solution to change the surface property of the polysilicon layer from hydrophobic to hydrophilic. Therefore, in the post-CMP cleaning process, organic contaminates on the surface of the polysilicon layer can be easily removed by HF solution and SC1 solution without the need of an additional H₂SO₄ cleaning process.

### BRIEF DESCRIPTION OF THE DRAWINGS

Implementations of the present technology will now be described, by way of example only, with reference to the attached figures.

FIG. 1 is a schematic diagram of a processing system for processing a substrate having a polysilicon layer according to an implementation.

FIG. 2 is a schematic diagram of a platen of a polishing module of the processing system in FIG. 1.

FIG. 3 is a schematic diagram showing a planarization process of the substrate on a platen of the processing system of FIG. 1.

FIG. 4 is a flowchart of a method of processing a substrate having a polysilicon layer according to an implementation of the present disclosure.

### DETAILED DESCRIPTION

The present disclosure will now be described more fully hereinafter with reference to the accompanying drawings, in which example implementations of the disclosure are shown.

This disclosure may, however, be implemented in many different forms and should not be construed as limited to the example implementations set forth herein. Rather, these example implementations are provided so that this disclosure will be thorough and complete, and will fully convey the scope of the disclosure to those skilled in the art. Like reference numerals refer to like elements throughout.

The terminology used herein is for the purpose of describing particular example implementations only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, actions, operations, elements, and/or components, but do not preclude the presence or addition of one or more other features, regions, integers, actions, operations, elements, components, and/or groups thereof.

It will be understood that the term “and/or” includes any and all combinations of one or more of the associated listed items. It will also be understood that, although the terms first, second, third etc. may be used herein to describe various elements, components, regions, parts and/or sections, these elements, components, regions, parts and/or sections should not be limited by these terms. These terms are only used to distinguish one element, component, region, part or section from another element, component, region, layer or section. Thus, a first element, component, region, part or section discussed below could be termed a second element, component, region, layer or section without departing from the teachings of the present disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

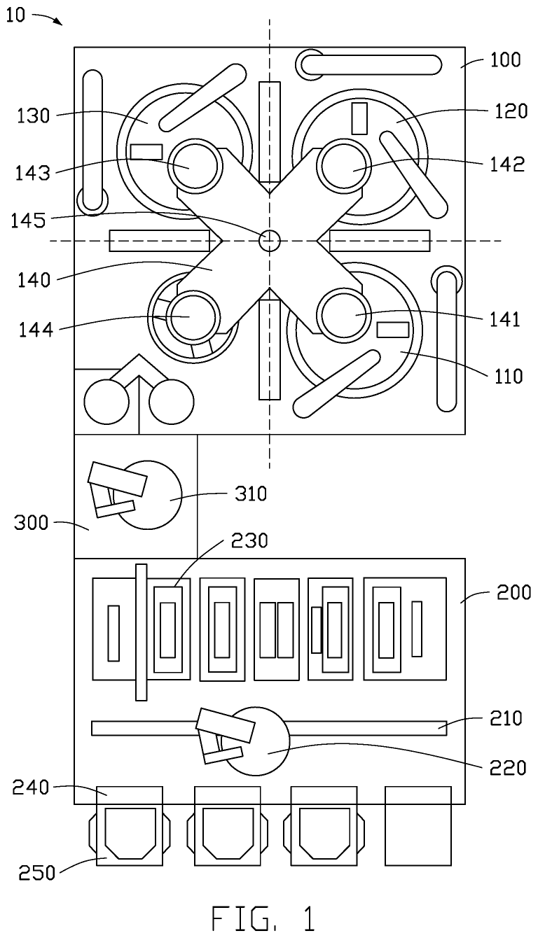

The description will be made as to the example implementations of the present disclosure in conjunction with the accompanying drawings in FIGS. 1 to 4. Reference will be made to the drawing figures to describe the present disclosure in detail, wherein depicted elements are not necessarily shown to scale and wherein like or similar elements are designated by same or similar reference numeral through the several views and same or similar terminology.

The present disclosure will be further described hereafter in combination with the accompanying figures.

Referring to FIG. 1, a processing system of processing a semiconductor substrate having a polysilicon layer is illustrated. As shown in FIG. 1, a processing system 10 includes a polishing module 100 and a cleaning module 200 coupled to the polishing module 100. The processing system 10 further includes a transfer region 300 disposed between the polishing module 100 and the cleaning module 200. The transfer region 300 includes a robot 310 for transferring the substrate to the polishing module 100 or the cleaning module 200. The substrate may be a silicon wafer having a dielectric layer and a polysilicon layer on top of the dielectric layer.

The polishing module 100 includes a plurality of polishing platens (e.g., three platens 110, 120, 130; the number of platens may vary and is not limited thereto) and a carousel 140 supported above the platens 110-130. The platens 110-130 may be placed at substantially equal angular intervals around, and/or at substantially equal distances from a rotation axis 145 of the carousel 140. The carousel 140 is cross-shaped with carrier heads (e.g., four carrier heads 141, 142, 143, and 144) spaced at substantially equal angular intervals (e.g., at 90 degree intervals) around the rotation axis 145 of the carousel 140. Each of the carrier heads 141-144 secures one substrate, for example, by vacuum chucking or by a retaining ring. The carousel 140 rotates about the rotation axis 145 to transport the carrier heads 141-144 with the substrates between the platens 110-130. Each of the carrier heads 141-144 may be vertically movable, or include a vertically movable lower portion for lowering the substrate to one of the platens 110-130 for planarization. Each of the carrier heads 141-144 may be independently rotatable by a motor.

The cleaning module 200, in one implementation, is a rectangular-shaped cabinet. The cleaning module 200 washes the substrate after planarization to remove excess debris. As shown in FIG. 1, the cleaning module 200 may be a batch type cleaning module. The cleaning module 200 includes a plurality of tanks 230 for containing different cleaning agents for cleaning the substrate. The cleaning agent may be SC1 Standard Clean 1 (SC1), HF solution, Buffered Oxide Etch (BOE), Sulfuric Peroxide Mixture (SPM; a mixture of H₂SO₄ and H₂O₂), or deionized water (DI water). The cleaning module 200 further includes a robot 220 positioned on a support rail 210. The robot 220 is configured to travel along the support rail 210 to move the substrate among the tanks 230. The cleaning module 200 may further include a plurality of cassette ports 240 to allow transport of the substrate from cassettes 250.

In another implementation, the cleaning module 200 may be a single-wafer cleaning module. While the batch type cleaning module washes several substrates in a tank, the single-wafer cleaning module is provided with a rotatable stage for cleaning one substrate in a chamber. Cleaning agents are provided to the surface of the substrate by nozzles in the chamber.

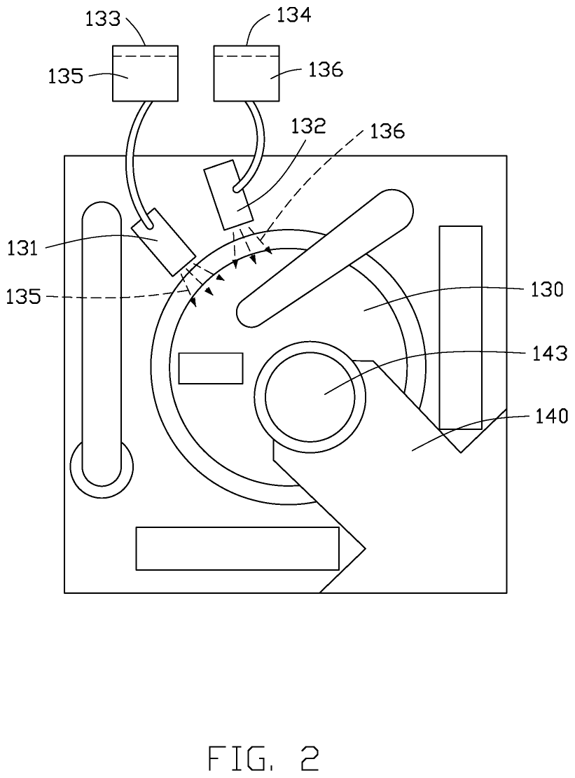

Referring to FIG. 2, each of the platens 110-130 of the polishing module 100 includes at least one nozzle for supplying liquid (such as abrasive slurry, DI water or other rinse agent) to the platen. Using platen 130 as an example, as shown in FIG. 2, the platen 130 includes two nozzles 131, 132 respectively connected to containers 133, 134. In one implementation, the nozzle 131 sprays abrasive slurry 135 stored in the container 133; and the nozzle 132 sprays DI water 136 stored in the container 134. The structure of platens 110,120 are similar to that of the platen 130, while the nozzles of platen 110,120 may provide different liquids to meet the requirement of the process for platens 110, 120.

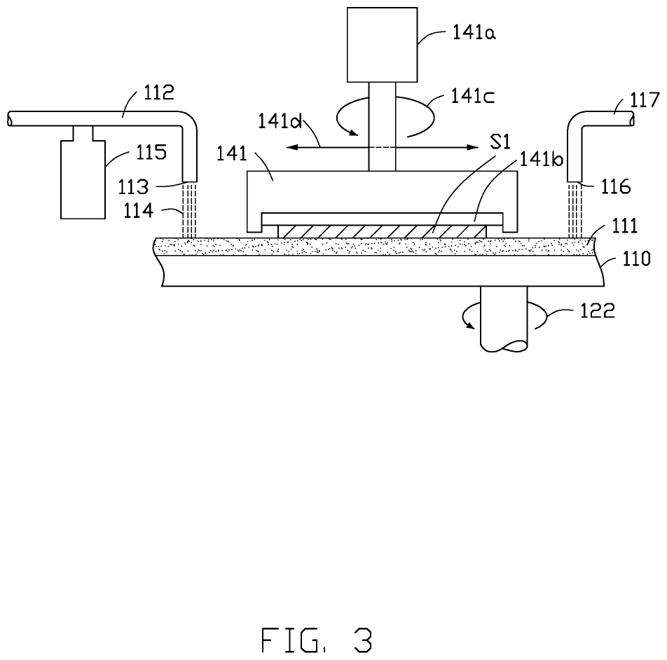

Referring to FIG. 3, a schematic diagram showing the polarization process is illustrated. Using the platen 110 as an example, one of the carrier head (e.g., carrier head 141) holds a substrate S1 above the platen 110. A membrane 141b is positioned between the carrier head 141 and the substrate S1, with the substrate S1 being held against membrane 141b by vacuum chucking. The carrier head 141 is provided to be continuously rotated by a drive motor 141a, in direction 141c, and optionally reciprocated transversely in directions 141d. Accordingly, the combined rotational and transverse movements of the substrate S1 are intended to reduce the variability in material removal rate across the surface of the substrate S1. The platen 110 is rotated in direction 122. A polishing pad 111 is mounted on the platen 110. As compared to the substrate S1, the platen 110 is provided with a relatively large surface area to accommodate the translational movement of the substrate S1 on the carrier head 141 across the surface of the polishing pad 111. A supply tube 112 is mounted above the platen 110 to deliver a stream of abrasive slurry 114, which is dripped onto the surface of the polishing pad 111 from a nozzle 113 of the supply tube 112. For the planarization of the polysilicon layer of the substrate, the abrasive slurry includes at least one of silica, ceria, alumina, titania, zirconia and germania (i.e., silica, ceria, alumina, titania, zirconia, germania, or any combination thereof). Preferably, the abrasive slurry includes at least one of silica and ceria (i.e., silica, ceria, or a combination of silica and ceria). The abrasive slurry 114 may be gravity fed from a tank (not shown), or otherwise pumped through supply tube 112. A filter 115 is coupled to the supply tube 112 to separate agglomerated or oversized particles in the abrasive slurry 114. Other nozzles 116 may be also provided to spray DI water or other solutions from other supply tubes 117 connected to storage tanks (not shown).

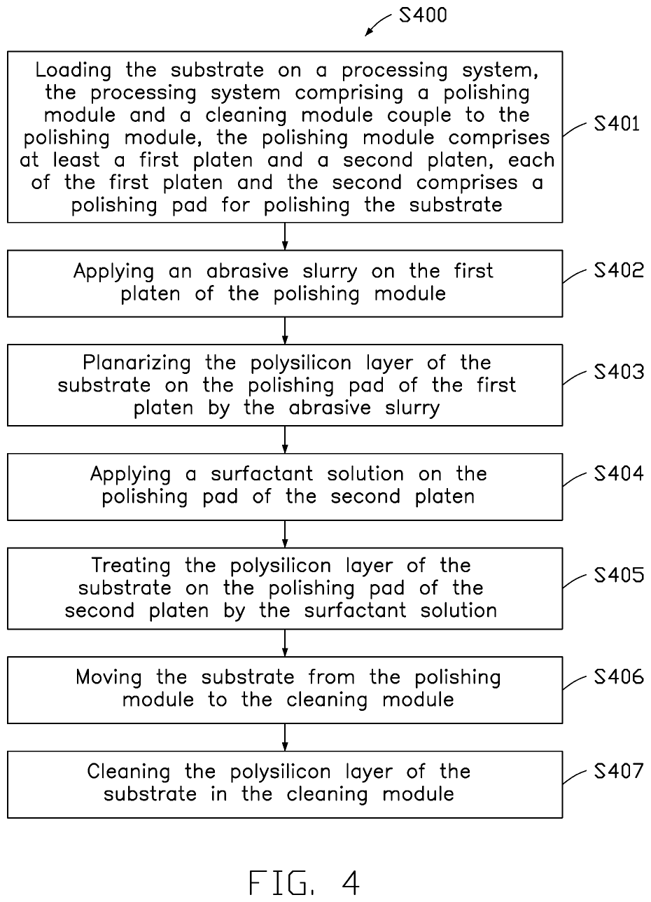

Referring to FIG. 4, a flowchart of a method S400 of processing a substrate having a polysilicon layer is provided. The method s400 may be performed by the processing system 10 shown in FIGS. 1-3. As shown in FIG. 4, the method S400 of an implementation of the present disclosure includes actions S401 to S407. In action S401, the substrate is loaded on the processing system 10 by the robot 310. As shown in FIG. 1, the processing system 10 includes the polishing module 100 and the cleaning module 200 coupled to the polishing module 100. The polishing module 100 includes at least a first platen and a second platen. In the implementation shown in FIG. 1, the polishing module 100 includes three platens 110, 120, and 130. Each of the platens 110, 120, and 130 includes a polishing pad (e.g., polishing pad 111 of platen 110 shown in FIG. 3) for polishing the substrate.

In action S402, an abrasive slurry is applied on the first platen of the polishing module 100. In action S403, the polysilicon layer of the substrate is planarized on the polishing pad of the first platen by the abrasive slurry. The abrasive slurry includes at least one of silica, ceria, alumina, Mania, zirconia and germania. Preferably, the abrasive slurry includes at least one of silica and ceria. The planarization process may be referred to FIG. 3 without further description. In one implementation, the actions S402 and S403 may be performed on the platen 110. In another implementation, the actions S402 and S403 may be performed on both of the platens 110 and 120. The planarization process of the polysilicon layer on the platen 110 and the platen 120 may have the same or different conditions (such as composition of slurry, polishing rate, polishing time, etc.).

In action S404, a surfactant solution is applied on the polishing pad of the second platen. In action S405, the polysilicon layer of the substrate is treated on the polishing pad of the second platen by the surfactant solution. The surfactant solution is an aqueous non-ionic surfactant solution. In an implementation, the non-ionic surfactant solution includes 0.1-5 wt % of alcohol ethoxylates. Alcohol ethoxylates are common non-ionic surfactants obtained from reacting alcohols with phoenols. The chemical structure of alcohol ethoxylates is R(OC₂H₄)ₙOH, wherein n ranges from 1 to 10. The non-ionic surfactant solution may be provided from the nozzles connected to the platens (such as the nozzle 131 or 132 for platen 130 shown in FIG. 2). The surface of the polysilicon layer after planarization is hydrophobic due to the Si—O bonds formed on the surface. Organic contaminates (e.g., polish pad side product, clean brush debris, surfactant of slurry) are likely to adhere to the surface of the polysilicon layer after the planarization process. A hydrophobic surface has large contact angles with aqueous cleaning solution, which reduces the performance of cleaning processes. Therefore, an additional H₂SO₄ cleaning process is required to remove the organic contaminates after the planarization of polysilicon layer to prevent defects on the substrate. In the action S405, surface property of the polysilicon layer changes from hydrophobic to hydrophilic after being treated by the surfactant solution. More specifically, surface treatment by alcohol ethoxylates changes the hydrophobic Si—O bonds into hydrophilic Si—OH bonds. Therefore, the organic contaminates can be easily removed without the need of the H₂SO₄ cleaning process. In one implementation, the actions of S404 and S405 may be performed on the platen 120, while the actions of S402 and S403 are performed on the platen 110; the platen 130 is a dummy platen in this case. In another implementation, the actions of S404 and S405 may be performed on the platen 130, while the actions of S402 and S403 are performed on both of the platens 110 and 120.

In action S406, after the surface treatment of the polysilicon layer, the substrate is moved from the polishing module 100 to the cleaning module 200 by the robot 310. In action S407, the polysilicon layer of the substrate is cleaned in the cleaning module 200. As described above, since the surface treatment of the action S405 changes the surface property of the polysilicon layer from hydrophobic to hydrophilic, the surface of the polysilicon layer may be cleaned by HF solution and SC1 Standard Cleaning 1 (SC1) solution, without the need of an additional H₂SO₄ solution. A hydrophilic surface has reduced contact angles with aqueous HF solution and SC1 solution. Therefore, the organic contaminates can be easily removed by HF solution and SC1 solution. In one implementation, the cleaning module 200 may be a batch-type cleaning module as shown in FIG. 1. The HF solution and SC1 solution are respectively disposed in the tanks 230. By immersing the substrate into the tanks 230 for a predetermined period of time, the substrate is cleaned. In another implementation, the cleaning module 200 may be a single-wafer cleaning module. The HF solution and SC1 solution are provided to the surface of the polysilicon layer of the substrate by the nozzles. By spinning the substrate on a rotatable stage, the surface of the polysilicon layer may be cleaned.

The present disclosure also is directed to a processing system for processing a substrate having a polysilicon layer. The processing system may be referred to the processing system 10 illustrated in FIGS. 1-3. As shown in FIG. 1, the processing system 10 includes a polishing module 100 and a cleaning module 200. The polishing module 100 includes at least a first platen and a second platen. In FIG. 1, the polishing module 100 includes three platens; that is, the first platen 110, the second platen 120, and a third platen 130. Each of the platens 110-130 includes at least one nozzle (e.g., nozzles 131, 132 for platen 130 in FIG. 2). The first platen 110 includes a first nozzle configured to provide an abrasive slurry for planarizing the polysilicon layer of the substrate. The second platen 120 includes a second nozzle configured to provide a surfactant solution to treat the polysilicon layer. The polishing module 100 further includes a carousel 140 having a rotation axis 145 disposed above the first platen 110, the second platen 120 and the third platen 130. The carousel 140 includes a plurality of carrier heads (e.g., four carrier heads 141-144 in FIG. 1) configured to secure the substrate. One carrier head secures one substrate. The carousel 140 rotates about the rotation axis to transport the carrier heads 141-144 among platens 110-130. Each of the carrier heads 141-144 is vertically movable for lowering the substrate to one of the platens 110-130 for polishing. Each of the carrier heads 141-144 may be independently rotatable by a motor (not shown in the figures).

Each of the first platen 110, the second platen 120 and the third platen 130 includes a polishing pad (e.g., polishing pad 111 of platen 110 in FIG. 3). The abrasive slurry is provided to the polishing pad by the first nozzle of the first platen 110 to planarize the polysilicon layer of the substrate. The abrasive slurry includes at least one of silica, ceria, alumina, titania, zirconia and germania. In an implementation, the abrasive slurry includes at least one of silica and ceria. The surfactant solution is provided on the polishing pad of the second platen 120 by the second nozzle. The surfactant solution includes 0.1 wt % to 5 wt % of non-ionic surfactant. In an implementation, the non-ionic surfactant is alcohol ethoxylates. The surface property of the polysilicon layer changes from hydrophobic to hydrophilic after being treated by the surfactant solution.

The polysilicon layer is cleaned by HF solution and SC1 solution in the cleaning module 200. In one implementation, the cleaning module 200 may be a batch type cleaning module having a plurality of tanks with different cleaning agents. By immersing the substrate in the tanks for a predetermined period of time, the polysilicon layer of the substrate is cleaned by HF solution and SC1 solution. In another implementation, the cleaning module may be a single-wafer cleaning module. While the batch type cleaning module washes several substrates in a tank, the single-wafer cleaning module is provided with a rotatable stage for cleaning one substrate in a chamber. Cleaning agents (e.g., HF solution and SC1 solution) are provided to the surface of the substrate by the nozzles in the chamber. Since the surface of the polysilicon layer of the substrate becomes hydrophilic after treated by the surfactant solution, organic contaminates on the surface of the polysilicon layer can be easily removed by HF solution and SC1 solution, without the need of an additional H₂SO₄ cleaning process.

The processing system 10 may further include a transfer region 300 disposed between the polishing module 100 and the cleaning module 200. The transfer region 300 includes a robot 310 configured to transfer the substrate between the polishing module 100 and the cleaning module 200.

As described above, the implementations of the present disclosure use a non-ionic surfactant solution to change the surface property of the polysilicon layer from hydrophobic to hydrophilic. Therefore, in the post-CMP cleaning process, organic contaminates on the surface of the polysilicon layer can be easily removed by HF solution and SC1 solution without the need of an additional H₂SO₄ cleaning process.

The implementations shown and described above are only examples. Many details are often found in the art such as the other features of a method of processing a substrate having a polysilicon layer and processing system thereof. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the implementations described above may be modified within the scope of the claims.

What is claimed is:

1. A method of processing a substrate having a polysilicon layer, the method comprising:
loading the substrate on a processing system, the processing system comprising a polishing module and a cleaning module couple to the polishing module, the polishing module comprising at least a first platen and a second platen, each of the first platen and the second platen comprising a polishing pad for polishing the substrate;
applying an abrasive slurry on the first platen of the polishing module;
planarizing the polysilicon layer of the substrate on the polishing pad of the first platen by the abrasive slurry;
applying a surfactant solution on the polishing pad of the second platen; and
treating the polysilicon layer of the substrate on the polishing pad of the second platen by the surfactant solution.

2. The method of claim 1, wherein the abrasive slurry comprises at least one of silica, ceria, alumina, titania, zirconia and germania.

3. The method of claim 1, wherein the surfactant solution is a non-ionic surfactant solution.

4. The method of claim 3, wherein the non-ionic surfactant solution comprises 0.1 wt % to 5 wt % of non-ionic surfactant.

5. The method of claim 4, wherein the non-ionic surfactant is alcohol ethoxylates.

6. The method of claim 1, further comprising:
moving the substrate from the polishing module to the cleaning module; and
cleaning the polysilicon layer of the substrate in the cleaning module.

7. The method of claim 6, wherein the polysilicon layer is cleaned by a hydrogen fluoride (HF) solution and a standard cleaning 1 (SC1) solution in the cleaning module.

8. The method of claim 1, wherein surface property of the polysilicon layer changes from hydrophobic to hydrophilic after being treated by the surfactant solution.

9. A processing system for processing a substrate having a polysilicon layer, the processing system comprising:
a polishing module comprising at least a first platen and a second platen, wherein the first platen comprises a first nozzle configured to provide an abrasive slurry for planarizing the polysilicon layer of the substrate, the second platen comprises a second nozzle configured to provide a surfactant solution for treating the polysilicon layer;
a cleaning module coupled to the polishing module for cleaning the substrate; and
a transfer region disposed between the polishing module and the cleaning module, and comprising a robot configured to transfer the substrate between the polishing module and the cleaning module.

10. The processing system of claim 9, wherein each of the first platen and the second platen comprises a polishing pad, and the surfactant solution is provided on the polishing pad of the second platen by the second nozzle.

11. The processing system of claim 9, wherein the abrasive slurry comprises at least one of silica, ceria, alumina, titania, zirconia and germania.

12. The processing system of claim 9, wherein the surfactant solution is a non-ionic surfactant solution.

13. The processing system of claim 12, wherein the non-ionic surfactant solution comprises 0.1 wt % to 5 wt % of non-ionic surfactant.

14. The processing system of claim 13, wherein the wherein the non-ionic surfactant is alcohol ethoxylates.

15. The processing system of claim 9, wherein the polysilicon layer is cleaned by a HF solution and a SC1 solution in the cleaning module.

16. The processing system of claim 9, wherein surface property of the polysilicon layer changes from hydrophobic to hydrophilic after being treated by the surfactant solution.

17. The processing system of claim 9, wherein the cleaning module is a batch type cleaning module.

18. The processing system of claim 9, wherein the cleaning module is a single-wafer cleaning module.

19. The processing system of claim 9, wherein the polishing module further comprises a carousel having a rotation axis disposed above the first and second platens, the carousel comprises a plurality of carrier heads configured to secure the substrate, and the carousel rotates about the rotation axis to transport the carrier heads between the first and second platens.

20. The processing system of claim 19, wherein each of the carrier heads is vertically movable.
